(19) United States
(12) Patent Application Publication
(10) Pub. No.: US 2026/0018544 A1
(43) Pub. Date: Jan. 15, 2026

(54) SEMICONDUCTOR CHIP AND SEMICONDUCTOR PACKAGE INCLUDING THE SAME

(71) Applicant: SAMSUNG ELECTRONICS CO., LTD., Suwon-si (KR)

(72) Inventors: Hyunggyun NOH, Suwon-si (KR); Dongmin KIM, Suwon-si (KR); Seohyeon KIM, Suwon-si (KR); Woongkee KIM, Suwon-si (KR); Jeongdu KIM, Suwon-si (KR); Gunhee BAE, Suwon-si (KR); Deokseon CHOI, Suwon-si (KR); Wonhong CHOI, Suwon-si (KR)

(73) Assignee: SAMSUNG ELECTRONICS CO., LTD., Suwon-si (KR)

(21) Appl. No.: 19/020,743

(22) Filed: Jan. 14, 2025

(30) Foreign Application Priority Data
Jul. 15, 2024 (KR) 10-2024-0093341

(51) Int. Cl. H01L 23/00; H01L 23/48; H01L 25/07

(52) U.S. Cl. CPC H01L 24/05; H01L 23/481; H01L 24/06; H01L 25/074; H01L 2224/0401; H01L 2224/05554; H01L 2224/05555; H01L 2224/05576; H01L 2224/0603; H01L 2224/06051; H01L 2224/06177; H01L 2225/06513; H01L 2225/06517; H01L 2225/06541

(57) ABSTRACT

A semiconductor chip may include: a semiconductor substrate; a through silicon via that vertically penetrates the semiconductor substrate; an integrated device layer on a first surface of the semiconductor substrate and including integrated devices; a multi-wiring layer on the integrated device layer and including layers of wires; an upper metal layer on the multi-wiring layer and connected to the wires; and a lower metal layer on a second surface of the semiconductor substrate. The semiconductor substrate may include a lower bump area on the second surface of the semiconductor substrate, the lower bump area including bump pads thereon, and the lower metal layer may be on a periphery of the lower bump area.

### CROSS-REFERENCE TO RELATED APPLICATION

This application is based on and claims priority under 35 U.S.C. § 119 to Korean Patent Application No. 10-2024-0093341, filed on Jul. 15, 2024, in the Korean Intellectual Property Office, the disclosure of which is incorporated by reference herein in its entirety.

### BACKGROUND

### 1. Field

The disclosure relates to a semiconductor chip and a semiconductor package. Specifically, the disclosure relates to a semiconductor chip including metal layers on top and bottom ends thereof, and a semiconductor package including the semiconductor chip.

### 2. Description of Related Art

With the rapid development of the electronics industry and the demands of users, electronic devices are becoming smaller and lighter. As electronic devices become smaller and lighter, a semiconductor package used therein is also becoming smaller and lighter, and higher integration of semiconductor devices is used. In order to achieve high performance and large capacity along with miniaturization and weight reduction, research and development are continuously being conducted on semiconductor chips including through silicon vias (TSVs) and semiconductor packages in which the semiconductor chips are stacked. In a semiconductor package in which semiconductor chips are stacked, stacking reliability of semiconductor chips is a consideration.

In a process of manufacturing a semiconductor chip including a through silicon via, warpage may occur due to the difference in coefficient of thermal expansion (CTE) between a wafer and a metal layer arranged on the wafer for redistribution, and therefore, technology to control this is used.

### SUMMARY

The disclosure provides a reliable semiconductor chip and semiconductor package by controlling warpage of a wafer during a process of manufacturing a semiconductor chip including a through silicon via.

In addition, the objective to be solved by the disclosure is not limited to the above-mentioned ones, and other objectives may be clearly understood by those skilled in the art from the description below.

According to one or more example embodiments, a semiconductor chip may include: a semiconductor substrate; a through silicon via that vertically penetrates the semiconductor substrate; an integrated device layer on a first surface of the semiconductor substrate and including integrated devices; a multi-wiring layer on the integrated device layer and including layers of wires; an upper metal layer on the multi-wiring layer and connected to the wires; and a lower metal layer on a second surface of the semiconductor substrate. The semiconductor substrate may include a lower bump area on the second surface of the semiconductor substrate, the lower bump area including bump pads thereon, and the lower metal layer may be on a periphery of the lower bump area.

According to one or more example embodiments, a semiconductor chip may include: a semiconductor substrate; a through silicon via that vertically penetrates the semiconductor substrate; an integrated device layer on a first surface of the semiconductor substrate and including integrated devices; a multi-wiring layer on the integrated device layer and including layers of wires; an upper metal layer on the multi-wiring layer and connected to an uppermost wire of the multi-wiring layer through a via contact, the upper metal layer being on an upper metal layer area of the first surface of the semiconductor substrate; an upper bump pad on an upper bump area of the first surface of the semiconductor substrate; a lower bump pad on a lower bump area of a second surface of the semiconductor substrate; and a lower metal layer on a lower metal layer area of the second surface of the semiconductor substrate, the lower metal layer area being on a periphery of the lower bump area. The lower metal layer may include a material having a coefficient of thermal expansion (CTE) greater than a CTE of the semiconductor substrate, and the lower metal layer may be shaped as one of: a plate, a serpent, a plurality of metal pads, or a plurality of metal lines.

According to one or more example embodiments, a semiconductor package may include: a first semiconductor chip; and at least one second semiconductor chip stacked on the first semiconductor chip. The at least one second semiconductor chip may include: a semiconductor substrate; a through silicon via that vertically penetrates the semiconductor substrate; an integrated device layer on a first surface of the semiconductor substrate and having integrated devices; a multi-wiring layer on the integrated device layer and including layers of wires; an upper metal layer on the multi-wiring layer and connected to the wires; bump pads on a lower bump area on a second surface of the semiconductor substrate; and a lower metal layer on the second surface of the semiconductor substrate. The lower metal layer may be on a periphery of the lower bump area, and the at least one second semiconductor chip is stacked such that a first surface of the at least one second semiconductor chip faces the first semiconductor chip.

### BRIEF DESCRIPTION OF THE DRAWINGS

Embodiments will be more clearly understood from the following detailed description taken in conjunction with the accompanying drawings in which:

FIG. 1 is a plan view schematically illustrating a semiconductor chip according to one or more embodiments;

FIG. 2 is a bottom view schematically illustrating a semiconductor chip according to one or more embodiments;

FIG. 3 is an enlarged view of portion A of the semiconductor chip of FIG. 1;

FIG. 4 is a schematic cross-sectional view of the semiconductor chip of FIG. 3 taken along line I-I′;

FIG. 5 is a bottom view schematically illustrating a semiconductor chip according to one or more embodiments;

FIG. 6A is an enlarged view of portion B of FIG. 5;

FIG. 6B is an enlarged view of portion B of FIG. 5;

FIG. 7 is a bottom view schematically illustrating a semiconductor chip according to one or more embodiments;

FIG. 8A is an enlarged view of portion C of FIG. 7;

FIG. 8B is an enlarged view of portion C of FIG. 7;

FIG. 9 is a bottom view schematically illustrating a semiconductor chip according to one or more embodiments;

FIG. 10 is a bottom view schematically illustrating a semiconductor chip according to one or more embodiments;

FIG. 11 is a bottom view schematically illustrating a semiconductor chip according to one or more embodiments;

FIG. 12 is a bottom view schematically illustrating a semiconductor chip according to one or more embodiments;

FIG. 13 is a bottom view schematically illustrating a semiconductor chip according to one or more embodiments; and

FIG. 14 is a cross-sectional view schematically illustrating a semiconductor package according to one or more embodiments.

### DETAILED DESCRIPTION

Hereinafter, embodiments will be described more fully with reference to the accompanying drawings. In the drawings, like elements are labeled like reference numerals and repeated description thereof will be omitted.

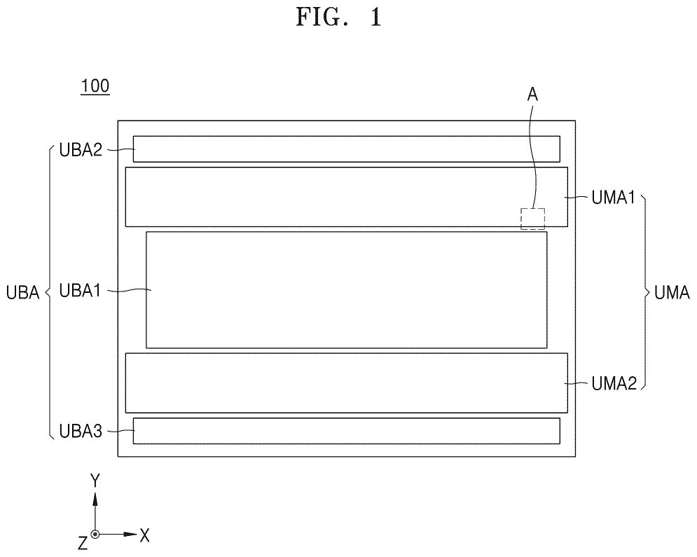

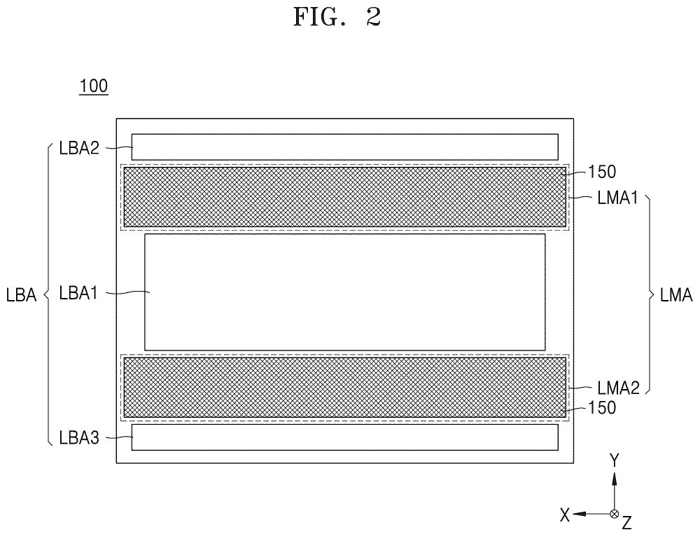

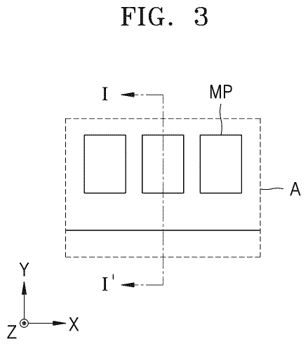

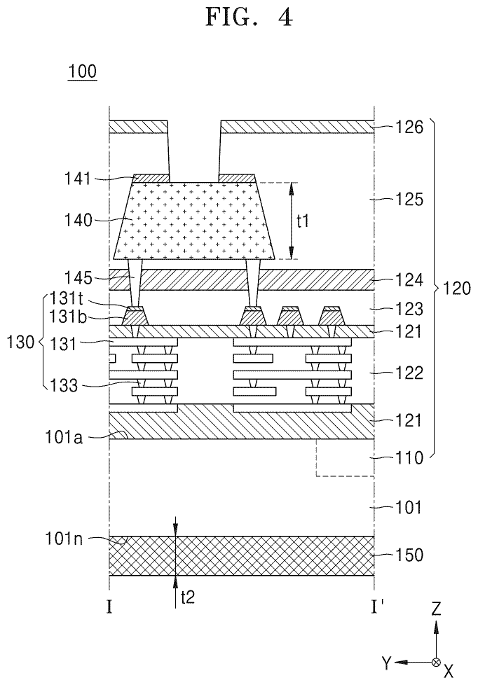

FIG. 1 is a plan view schematically illustrating a semiconductor chip 100 according to one or more embodiments. FIG. 2 is a bottom view schematically illustrating the semiconductor chip 100 according to one or more embodiments. FIG. 3 is an enlarged view of portion A of the semiconductor chip 100 of FIG. 1. FIG. 4 is a schematic cross-sectional view of the semiconductor chip 100 of FIG. 3 taken along line I-I′.

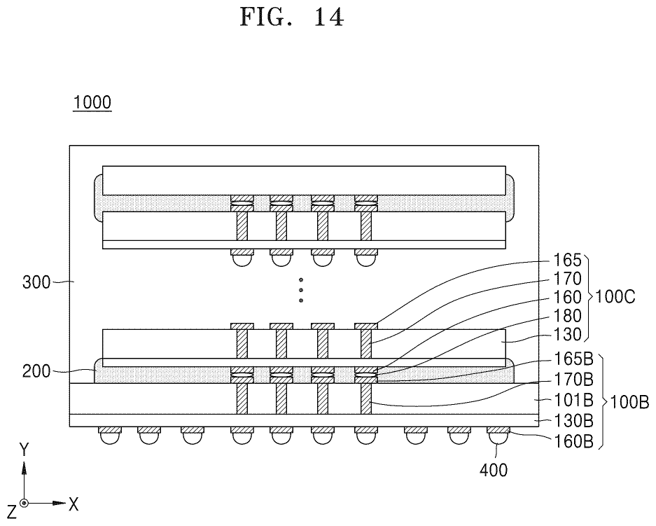

Referring to FIG. 1, the semiconductor chip 100 according to one or more embodiments may include, in a planar view, on an upper surface thereof, an upper bump area UBA and an upper metal layer area UMA. A bump pad (see 160 in FIG. 14) may be arranged in the upper bump area UBA, and a metal pad MP may be arranged in the upper metal layer area UMA. The bump pad (see 160 of FIG. 14) refers to a pad on which a bump (see 180 of FIG. 14) is arranged, and the metal pad MP may be a portion of an upper metal layer 140 that functions as a redistribution layer electrically connected to a multi-wiring layer 130 on the upper surface of the semiconductor chip 100.

The upper bump area UBA may be arranged in a center and a periphery of the semiconductor chip 100, and the upper metal layer area UMA may be arranged in a region other than the upper bump area UBA. In one or more embodiments, the upper bump area UBA may include a first upper bump area UBA1 disposed in a central portion of the semiconductor chip 100, and a second upper bump area UBA2 and a third upper bump area UBA3 respectively disposed at both outer sides of the semiconductor chip 100 and spaced apart from the first upper bump area UBA1 in a second horizontal direction (Y direction).

The upper metal layer area UMA may include a first upper metal layer area UMA1 positioned between the first upper bump area UBA1 and the second upper bump area UBA2 and a second upper metal layer area UMA2 positioned between the first upper bump area UBA1 and the third upper bump area UBA3. However, the disclosure is not limited thereto, and the upper metal layer area UMA may correspond to all areas of an upper surface area of the semiconductor chip 100 other than the upper bump area UBA.

Referring to FIGS. 1 and 2, the semiconductor chip 100 according to one or more embodiments may include, in a planar view, on a lower surface thereof, a lower bump area LBA and a lower metal layer area LMA. A bump pad (see 165 in FIG. 14) may be arranged in the lower bump area LBA, and a lower metal layer 150 may be arranged in the lower metal layer area LMA. The lower metal layer 150 may be arranged on a lower surface of a wafer to alleviate warpage occurring due to the difference in thermal expansion coefficient between the wafer forming a semiconductor substrate 101 and the upper metal layer 140 arranged on an upper surface of the wafer in a manufacturing process of the semiconductor chip 100.

The lower bump area LBA is an area where bump pads (see 165 of FIG. 14) are arranged to electrically connect a plurality of semiconductor chips 100 to each other by bumps (see 180 of FIG. 14) when the semiconductor chips 100 are stacked in a vertical direction (Z direction). The lower bump area LBA may overlap with the upper bump area UBA in the vertical direction (Z direction). The lower metal layer area LMA is an area located at a periphery of the lower bump area LBA, and may correspond to the remaining area of the lower surface of the semiconductor chip 100 except the lower metal layer area LMA. The lower metal layer area LMA may overlap the upper metal layer area UMA in the vertical direction (Z direction).

The arrangement structure of the upper bump area UBA, the lower bump area LBA, the upper metal layer area UMA, and the lower metal layer area LMA in the semiconductor chip 100 of the present embodiment is not limited to the arrangement structure illustrated in FIGS. 1 and 2. For example, the arrangement structure of the upper bump area UBA, the lower bump area LBA, the upper metal layer area UMA, and the lower metal layer area LMA may vary according to the types of integrated devices arranged therein and the wiring structure of wiring layers. For reference, a surface illustrated in FIG. 1 may correspond to an active surface of the semiconductor chip 100, and a surface illustrated in FIG. 2 may correspond to an inactive surface of the semiconductor chip 100. Accordingly, when the semiconductor chip 100 is stacked on a printed circuit board (PCB) or a buffer chip (see 100B of FIG. 14) to form a semiconductor package, the active surface may face downward.

Referring to FIGS. 1 to 4, the semiconductor chip 100 according to the present embodiment may include, from a vertical view, the semiconductor substrate 101, an integrated device layer 110, an interlayer insulating layer 120, the multi-wiring layer 130, the upper metal layer 140, and the lower metal layer 150. The semiconductor substrate 101 may include, for example, silicon (Si). However, the material of the semiconductor substrate 101 is not limited to silicon. For example, the semiconductor substrate 101 may include other semiconductor elements such as germanium (Ge), or a compound semiconductor such as SiC, GaAs, InAs, InP, etc. The semiconductor substrate 101 may have a silicon on insulator (SOI) structure. For example, the semiconductor substrate 101 may include a buried oxide (BOX) layer. The semiconductor substrate 101 may include a conductive region, such as a doped well or a doped structure. Additionally, the semiconductor substrate 101 may include various device isolation structures such as a shallow trench isolation (STI) structure.

The semiconductor substrate 101 may have an active surface 101a and a non-active surface 101n opposite thereto, and the integrated device layer 110 in which a plurality of integrated devices are formed may be arranged on the active surface 101a. For reference, in the cross-sectional view of FIG. 4, a portion of the semiconductor substrate 101 including the integrated device layer 110 is illustrated with a relatively small thickness in order to emphasize portions of the upper metal layer 140, the lower metal layer 150, and the multi-wiring layer 130. However, as may be seen in FIG. 14, in reality, a through silicon via 170 and a portion of the semiconductor substrate 101, which includes the integrated device layer 110, may have a greater thickness than the interlayer insulating layer 120 and the multi-wiring layer 130.

The integrated device layer 110, the interlayer insulating layer 120, the multi-wiring layer 130, and the upper metal layer 140 described below may be arranged on an upper surface of the semiconductor substrate 101, i.e., the active surface 101a, and the lower metal layer 150 may be arranged on a lower surface of the semiconductor substrate 101, i.e., the non-active surface 101n.

The integrated devices of the integrated device layer 110 may include memory devices or logic devices. The memory devices may include, for example, dynamic random- access memory (DRAM), static random-access memory (SRAM), flash memory, electrically erasable and programmable read-only memory (EEPROM), phase-change random-access memory (PRAM), magnetic random-access memory (MRAM), or resistive random-access memory (RRAM) devices. The logic devices may include, for example, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slaver flip-flop, a latch, a counter, or buffer elements. Additionally, the logic devices may include an xPU, a central processing unit (CPU), a microprocessor unit (MPU), a graphics processing unit (GPU), a neutral network processing unit (NPU)), an application processor (AP), an application-specific integrated circuit (ASIC), etc.

In the semiconductor chip 100 of the present embodiment, the integrated device layer 110 may include memory devices, such as DRAM devices. In addition, the semiconductor chip 100 of the present embodiment is a high bandwidth memory (HBM) DRAM chip and may be used in an HBM package. The structure of the HBM package is described in detail with reference to FIG. 14.

The interlayer insulating layer 120 may be arranged on the semiconductor substrate 101. The interlayer insulating layer 120 may include first to sixth interlayer insulating layers 121 to 126. However, the number of layers of the interlayer insulating layer 120 is not limited thereto. The sixth interlayer insulating layer 126 of the interlayer insulating layer 120 may be referred to as a protective layer since the sixth interlayer insulating layer 126 has a function of protecting lower wiring layers and integrated devices.

The first interlayer insulating layer 121 and the fifth interlayer insulating layer 125 may include tetraethyl orthosilicate (TEOS). However, the material of the first interlayer insulating layer 121 is not limited to TEOS. For example, the first interlayer insulating layer 121 may include an oxide film such as phosphor silicate glass (PSG), boro-phosphor silicate glass (BPSG), undoped silicate glass (USG), plasma enhanced-TEOS (PE-TEOS), high density plasma-chemical vapor deposition (HDP-CVD), etc.

The second interlayer insulating layer 122 may include a low-k material. The second interlayer insulating layer 122 may be arranged within the first interlayer insulating layer 121. The second interlayer insulating layer 122 of the low-k dielectric material may reduce a parasitic capacitance and resistive capacitive (RC) delay may be improved. For example, the second interlayer insulating layer 122 may include an insulating material having a lower dielectric constant than silicon oxide (SiO₂). In one or more embodiments, the second interlayer insulating layer 122 may include a material having an ultra-low dielectric constant k of about 2.2 to about 2.4. The second interlayer insulating layer 122 may include a silicon oxide film containing carbon (C) or hydrocarbon (CₓH_{y}). For example, the second interlayer insulating layer 122 may include a SiOC layer or a SiCOH layer.

The third interlayer insulating layer 123 and the sixth interlayer insulating layer 126 may include an HDP-CVD oxide film. However, the material of the third interlayer insulating layer 123 and the sixth interlayer insulating layer 126 is not limited to the HDP-CVD oxide film. For example, various oxide films described with respect to the first interlayer insulating layer 121 and the fifth interlayer insulating layer 125 may be used in the third interlayer insulating layer 123 and the sixth interlayer insulating layer 126.

The fourth interlayer insulating layer 124 may include silicon nitride such as SiNₓ. However, the fourth interlayer insulating layer 124 is not limited to silicon nitride.

The multi-wiring layer 130 may be arranged on the integrated device layer 110. The multi-wiring layer 130 may include wires 131 of multiple layers and via contacts 133 connecting the wires 131 adjacent to each other in the vertical direction (Z direction). The via contact 133 may also connect the integrated devices on the semiconductor substrate 101 to the wires 131. In FIG. 4, the multi-wiring layer 130 including six layers of wires 131 is illustrated, but is not limited thereto.

The wires 131 and the via contacts 133 of the multi-wiring layer 130 may include a metal such as aluminum (Al), copper (Cu), or tungsten (W). In one or more embodiments, the wires 131 and the via contacts 133 may include a barrier layer and a wire metal layer. The barrier layer may include a metal such as Ti, Ta, Al, Ru, Mn, Co, W, or a nitride of the metal or an oxide of the metal, or may include an alloy such as cobalt tungsten phosphide (CoWP), cobalt tungsten boron (CoWB), or cobalt tungsten boron phosphide (CoWBP). The wiring metal layer may include at least one metal selected from W, Al, Ti, Ta, Ru, Mn, and Cu.

In one or more embodiments, an uppermost wire of the multi-wiring layer 130 may include a body 131b including aluminum (Al) and a top layer 131t of Ti/TiN on an upper surface of the body 131b. Additionally, the remaining wires 131 except for the uppermost wire of the multi-wiring layer 130 may include copper (Cu). In one or more embodiments, as illustrated in FIG. 4, the wires 131 of the first layer to the fifth layer may be disposed within the second interlayer insulating layer 122 of a low-k dielectric material, and the wire 131 of the sixth layer, which is the uppermost wire, may be disposed within the third interlayer insulating layer 123.

For reference, a through silicon via (TSV, see 170 of FIG. 14) penetrating the semiconductor substrate 101 may be arranged in a portion of each of the upper bump area UBA and the lower bump area LBA. The through silicon via 170 may be connected to the bump pad (see 160, 165 of FIG. 14) through the multi-wiring layer 130.

The upper metal layer 140 may be arranged on the multi-wiring layer 130. The upper metal layer 140 may be electrically connected to the multi-wiring layer 130 and may be used for redistribution. The upper metal layer 140 may be arranged such that a portion of an upper surface thereof is covered by the sixth interlayer insulating layer 126. For example, in a planar view, a central portion of the upper metal layer 140 may be exposed from a protective layer, for example, the sixth interlayer insulating layer 126, and an outer portion of the upper metal layer 140 may be arranged to be covered by the protective layer. In one or more embodiments, the central portion of the upper metal layer 140, which is an area exposed from the protective layer, may form the metal pad MP exposed on the upper surface of the semiconductor chip 100.

The upper metal layer 140 may include aluminum (Al). However, the material of the upper metal layer 140 is not limited to Al, and may include a metal such as copper (Cu) or zirconium (Zr) or an oxide of the metal.

A thickness t1 of the upper metal layer 140 may be about 0.01 μm to about 100 μm.

In one or more embodiments, a barrier layer 141 may be further formed on the upper surface of the upper metal layer 140. The barrier layer 141 may include, for example, a metal such as Ti, Ta, Al, Ru, Mn, Co, or W, or a nitride of the metal or an oxide of the metal. The barrier layer 141 may be arranged only on an outer portion of the upper metal layer 140 and may not be arranged on a central portion of the upper metal layer 140.

The upper metal layer 140 may be connected to an uppermost wire of the multi-wiring layer 130 through a top via contact 145. The top via contact 145 may include tungsten (W). However, the material of the top via contact 145 is not limited to W.

The lower metal layer 150 may be arranged on the lower surface of the semiconductor substrate 101. Referring to FIGS. 1 and 2 together with FIG. 4, the lower metal layer 150 may be arranged in the lower metal layer area LMA on the lower surface of the semiconductor substrate 101. That is, the lower metal layer 150 may be arranged on the periphery of the lower bump area LBA where the bump pad (see 165 of FIG. 14) is arranged. In one or more embodiments, the lower metal layer 150 may be arranged to correspond to the upper metal layer 140 arranged on the upper surface of the semiconductor substrate 101. Accordingly, in a manufacturing process of the semiconductor chip 100, vertical imbalance in a coefficient of thermal expansion (CTE), caused by the difference in CTE between the semiconductor substrate 101 and the upper metal layer 140 may be alleviated. Therefore, when a wafer is exposed to high temperatures during a semiconductor manufacturing process, warpage due to the difference in CTE between the wafer and the upper metal layer 140 may be minimized.

The lower metal layer 150 may include a material having a CTE greater than a CTE of the semiconductor substrate 101. In one or more embodiments, the semiconductor substrate 101 may include silicon (Si), and the lower metal layer 150 may include a material having a CTE of 2.6 ppm or greater. For example, the lower metal layer 150 may include Al, Cu or Zr. However, the material of the lower metal layer 150 is not limited thereto, and may include another type of metal or metal oxide.

In one or more embodiments, the lower metal layer 150 may have a plate shape. In FIG. 2, the lower metal layer 150 is illustrated as having a square plate shape, but is not limited thereto. The lower metal layer 150 may have various shapes. In addition, in FIG. 2, the lower metal layer 150 is illustrated, which is formed in a square plate shape and disposed in the first lower metal layer area LMA1 between the first lower bump area LBA1 and the second lower bump area LBA2 and in the second lower metal layer area LMA2 between the first lower bump area LBA1 and the third lower bump area LBA3, but is not limited thereto. As described above, the lower metal layer area LMA may correspond to all remaining areas that do not overlap with the lower bump area LBA, and the lower metal layer 150 may be formed to fill the lower metal layer area LMA. That is, the lower metal layer 150 may have a shape that fills the lower metal layer area LMA formed at the periphery of the lower bump area LBA.

A thickness t2 of the lower metal layer 150 may be a thickness that may minimize warpage due to the CTE difference between the upper metal layer 140 and the semiconductor substrate 101. In one or more embodiments, the thickness t2 of the lower metal layer 150 may be about 0.01 μm to about 100 μm.

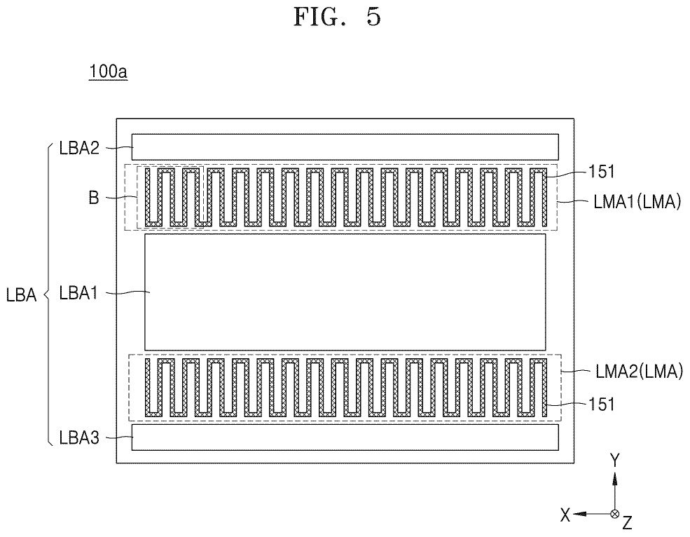

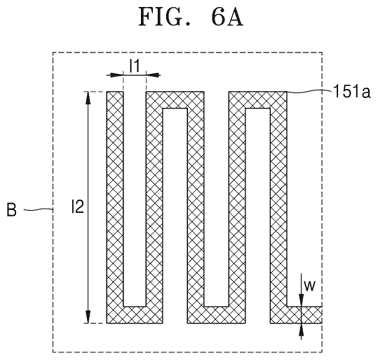

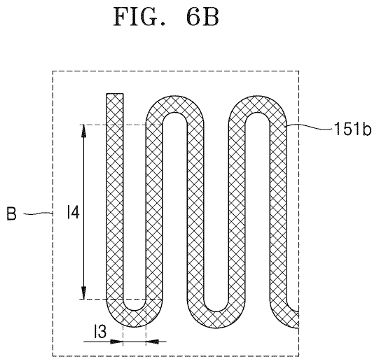

FIG. 5 is a bottom view schematically illustrating a semiconductor chip 100a according to one or more embodiments, and FIGS. 6A and 6B are enlarged views of portion B of FIG. 5. The semiconductor chip 100a of FIGS. 5 to 6B is almost identical or similar to the semiconductor chip 100 illustrated in FIGS. 1 to 4, except that the shape of the lower metal layer 150 is different. Therefore, the description of the components already provided with reference to FIGS. 1 to 4 will be omitted or simplified.

Referring to FIG. 5, a lower metal layer 151 may have a serpentine shape (i.e. shaped like a serpent) extending in a first horizontal direction (X direction) in a planar view. The lower metal layer 151 may have a serpentine shape in which a unit serpentine structure is repeated and extends in the first horizontal direction (X direction).

Referring to FIG. 6A, a lower metal layer 151a in a serpentine shape may have a shape in which a unit serpentine structure having a vertically bent shape is repeated. In one or more embodiments, the serpentine shape of the lower metal layer 151a may include a unit serpentine structure in which a horizontal length 11 and a vertical length 12 are each about 0.1 μm to about 100 μm.

Referring to FIG. 6B, a lower metal layer 151b of a serpentine shape may have a shape in which a unit serpentine structure with repeated straight and curved sections is repeated. The serpentine shape of the lower metal layer 151b may include a unit serpentine structure in which a width 13 of a curved portion and a width 14 of a straight portion are each about 0.1 μm to about 100 μm.

Referring to FIGS. 5 to 6B, one row of the serpentine-shaped lower metal layer 151 is arranged in each of the first lower metal layer area LMA1 and the second lower metal layer area LMA2, but the disclosure is not limited thereto. A plurality of rows of serpentine-shaped lower metal layers 151 may be arranged in each of the first lower metal layer area LMA1 and the second lower metal layer area LMA2.

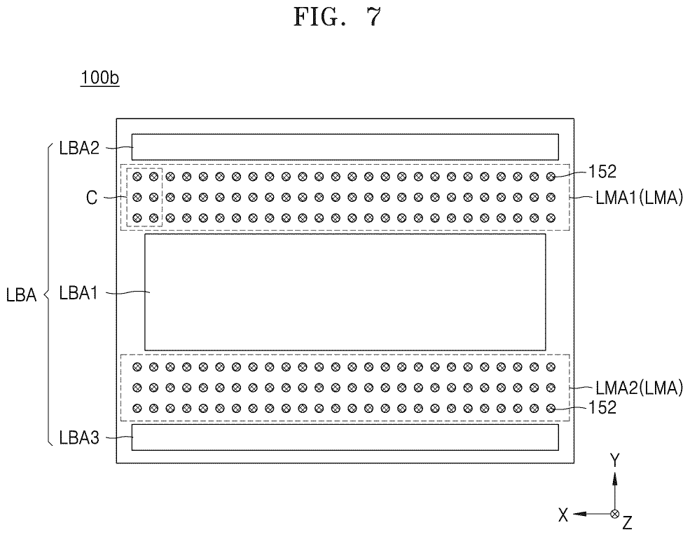

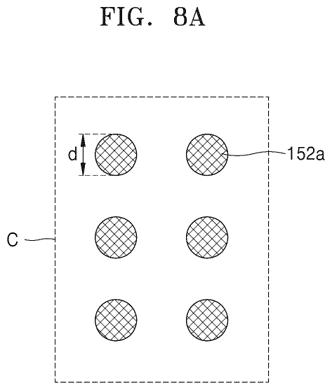

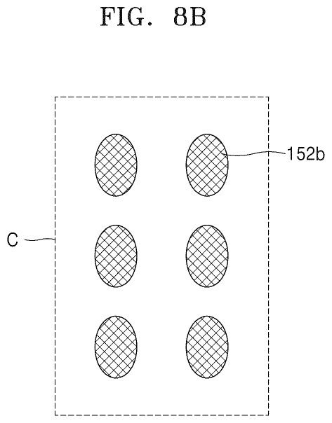

FIG. 7 is a bottom view schematically illustrating the semiconductor chip 100b according to one or more embodiments, and FIGS. 8A and 8B are enlarged views of portion C of FIG. 7. The semiconductor chip 100b of FIGS. 7 to 8B is almost identical or similar to the semiconductor chip 100 illustrated in FIGS. 1 to 4, except that the shape of the lower metal layer 150 is different. Therefore, the description of the components already provided with reference to FIGS. 1 to 4 will be omitted or simplified.

Referring to FIG. 7, a lower metal layer 152 may have a shape in which a plurality of metal pads are arranged. The lower metal layer 152 may be formed by arranging a plurality of metal pads in the first horizontal direction (X direction) and the second horizontal direction (Y direction).

Referring to FIG. 8A, a lower metal layer 152a may have a shape in which a plurality of circular metal pads are arranged. In one or more embodiments, the circular metal pads of the lower metal layer 152a may each have a diameter of about 0.1 μm to about 100 μm. Referring to FIG. 8B, a lower metal layer 152b may have a shape in which a plurality of oval metal pads are arranged.

In FIGS. 7 to 8B, three rows of metal pads are arranged in each of the first lower metal layer area LMA1 and the second lower metal layer area LMA2, but the disclosure is not limited thereto. The lower metal layer 152 having one or more rows of metal pads arranged may be arranged in each of the first lower metal layer area LMA1 and the second lower metal layer area LMA2. Additionally, the shape of each metal pad may include various shapes such as circular and oval, as well as semicircular and square shapes.

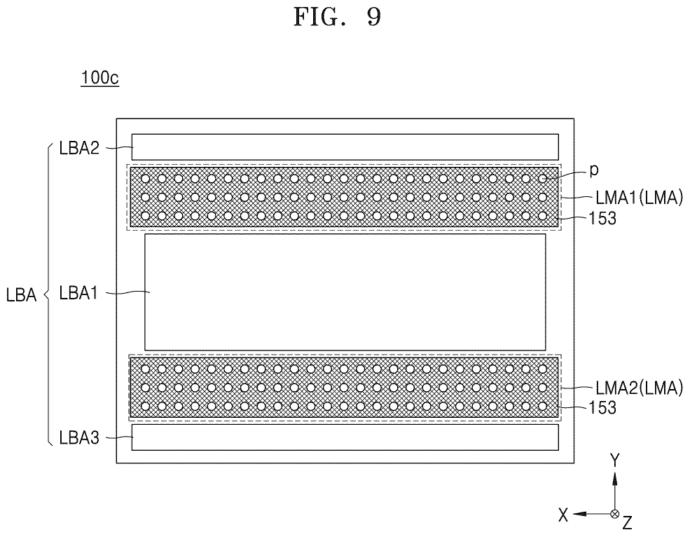

FIGS. 9 to 13 are bottom views schematically illustrating semiconductor chips 100c, 100d, 100e, 100f, and 100g according to one or more embodiments. The semiconductor chips 100c, 100d, 100e, 100f, and 100g illustrated in FIGS. 9 to 13 are almost identical or similar to the semiconductor chips 100 illustrated in FIGS. 1 to 4, except that the shape of the lower metal layer 150 is different. Therefore, the description of the components already provided with reference to FIGS. 1 to 4 will be omitted or simplified.

Referring to FIG. 9, a lower metal layer 153 may have a plate shape including a plurality of holes p therein. In FIG. 9, the lower metal layer 153 having a square plate shape including the plurality of holes p which are circular is illustrated, but is not limited thereto. The shape and number of holes p and the shape of the plate may vary.

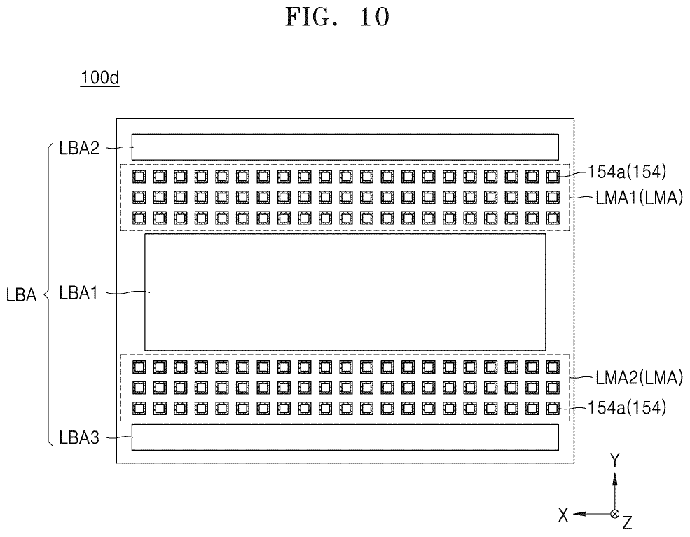

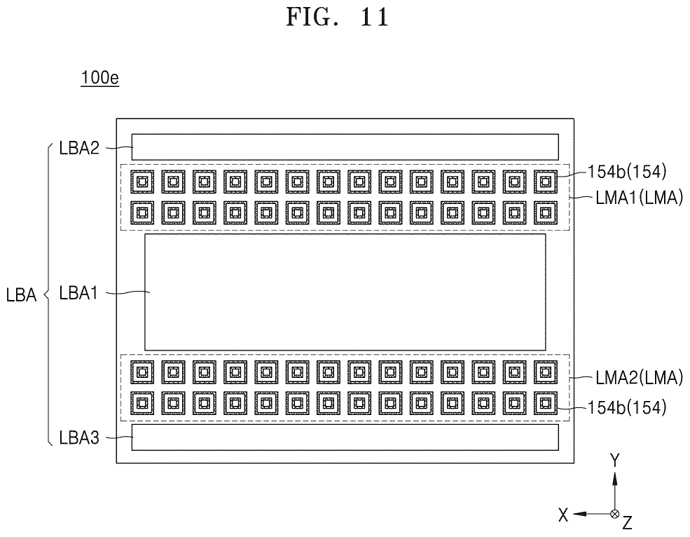

Referring to FIGS. 10 and 11, a lower metal layer 154 may have a shape in which a plurality of metal lines are arranged. A lower metal layer 154a may have a shape in which single square ring-shaped metal lines are arranged. Additionally, a lower metal layer 154b may have a shape in which metal lines having different sized square rings are arranged. The shape of the metal lines of the lower metal layer 154 may be changed into various shapes, such as a square ring or a circle.

In FIGS. 2 and 5 to 11, the lower metal layers 150, 151, 152, 153, and 154 having an identical shape arranged in the first lower metal layer area LMA1 and the second lower metal layer area LMA2 are illustrated, but the disclosure is not limited thereto. The lower metal layers 150, 151, 152, 153, and 154 of different shapes may be arranged in each of the first lower metal layer area LMA1 and the second lower metal layer area LMA2.

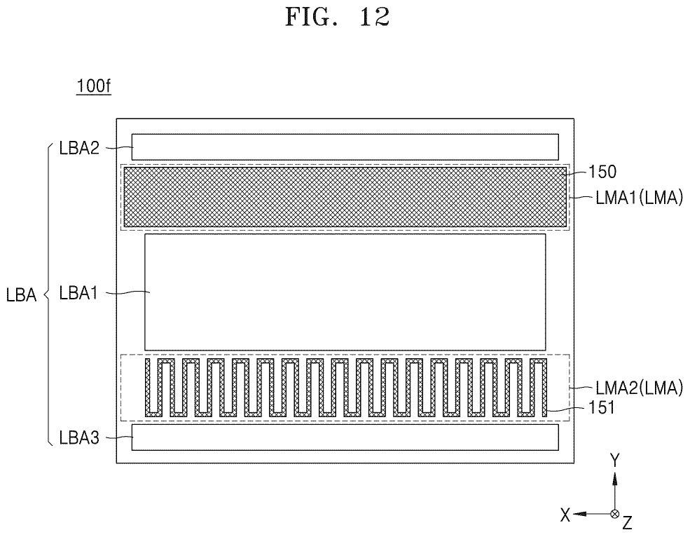

Referring to FIG. 12, the lower metal layer 150 having a square plate shape may be arranged in the first lower metal layer area LBA1, and the lower metal layer 151 having a serpentine shape may be arranged in the second lower metal layer area LBA2. However, the disclosure is not limited thereto, and the lower metal layers 150, 151, 152, 153, 154 having various shapes, described with reference to FIGS. 2 and 5 to 11, may be arranged in combination in the first lower metal layer area LMA1 and the second lower metal layer area LMA2. Here, the lower metal layers 150, 151, 152, 153, 154 that allow to minimize warpage due to the CTE difference between the upper metal layer 140 and the semiconductor substrate 101 may be combined and arranged in each of the first lower metal layer area LMA1 and the second lower metal layer area LMA2.

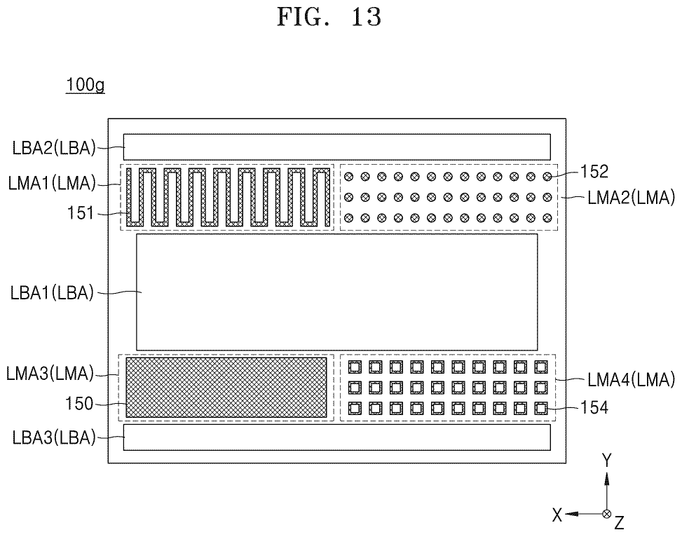

Also, referring to FIG. 13, the lower metal layer area LMA may be divided into four lower metal layer areas LMA1, LMA2, LMA3, and LMA4. In each of the lower metal layer areas LMA1, LMA2, LMA3, and LMA4, the lower metal layers 150, 151, 152, 153, and 154 of various shapes described with reference to FIGS. 2 and 5 to 11 may be arranged in combination.

Although the shape of the lower metal layers is described in detail with reference to FIGS. 2 and 5 to 13, the shape of the lower metal layer 150 is not limited to these shapes. The lower metal layer 150 may be implemented in various shapes so as to minimize warpage due to the CTE difference between the upper metal layer 140 and the semiconductor substrate 101. Additionally, the lower metal layer 150 may be configured in various shapes like the upper metal layer (see 140 in FIG. 4).

FIG. 14 is a cross-sectional view schematically illustrating a semiconductor package 1000 according to one or more embodiments. The one or more embodiments are described by also referring to FIG. 4, and description of those details provided above with reference to FIGS. 1 to 13 is briefly given or omitted.

Referring to FIG. 14, the semiconductor package 1000 of the present embodiment may include a buffer chip 100B, a core chip 100C, and a sealant 300. The buffer chip 100B may be arranged in a lowermost portion of the semiconductor package 1000. The buffer chip 100B may be greater in size than the core chips 100C positioned thereon. However, the size of the buffer chip 100B is not limited thereto. For example, the buffer chip 100B may have substantially the same size as that of the core chips 100C.

The buffer chip 100B may include a semiconductor substrate 101B, a wiring layer 130B, a through silicon via 170B, a lower electrode pad 160B, and an upper electrode pad 165B. The semiconductor substrate 101B may include a silicon substrate. However, the semiconductor substrate 101B is not limited to a silicon substrate. For example, the semiconductor substrate 101B may include another semiconductor element, such as germanium (Ge), or a compound semiconductor, such as silicon carbide (SiC), gallium arsenide (GaAs), indium arsenide (InAs), or indium phosphide (InP).

The semiconductor substrate 101B may include an integrated device layer therein. The integrated device layer may include multiple logic devices. Accordingly, the buffer chip 100B may be referred to as a logic chip or a control chip. The buffer chip 100B is arranged below the core chips 100C to integrate signals of the core chips 100C and transmit the same to the outside, and may also transmit signals and power from the outside to the core chips 100C. According to one or more embodiments, the buffer chip 100B may include a buffer memory device and a general memory device.

The wiring layer 130B may be arranged under the semiconductor substrate 101B and include multiple layers of wiring therein. The wiring layer 130B may correspond to a structure including the interlayer insulating layer 120 and the multi-wiring layer 130 of the semiconductor chip 100 of FIG. 5.

The through silicon via 170B may be arranged in a structure that penetrates the semiconductor substrate 101B. To describe the through silicon via 170B in further detail, in the semiconductor package 1000 of the present embodiment, the through silicon via 170B may have a via-middle structure. However, the disclosure is not limited thereto, and the through silicon via 170B may have a via-first or via-last structure. Here, the via-first structure may refer to a structure in which a through silicon via is formed before forming an integrated device layer, the via-middle structure may refer to a structure in which a through silicon via is formed after forming an integrated device layer but before forming a wiring layer, and the via-last structure may refer to a structure in which a through silicon via is formed after forming a wiring layer. In the present embodiment, in the semiconductor package 1000, due to the via-middle structure, the through silicon via 170B may extend through the semiconductor substrate 101B including an integrated device layer and to the wiring layer 130B.

A lower surface of the through silicon via 170B may be connected to the lower electrode pad 160B, and an upper surface of the through silicon via 170B may be connected to the upper electrode pad 165B. As illustrated in FIG. 14, the lower surface of the through silicon via 170B may be connected to the lower electrode pad 160B through the wiring layer 130B. On the other hand, the upper surface of the through silicon via 170B may be directly connected to the upper electrode pad 165B. A protective layer may be formed on an upper surface of the semiconductor substrate 101B and a lower surface of the wiring layer 130B, and the lower electrode pad 160B and the upper electrode pad 165B may be exposed from the protective layer. A connection terminal 400 may be arranged on the lower electrode pad 160B, and a bump 180 of the core chip 100C may be arranged on the upper electrode pad 165B.

The connection terminal 400 may be connected to the through silicon via 170B through the lower electrode pad 160B and the wiring layer 130B. The connection terminal 400 may include a conductive material, such as copper (Cu), aluminum (Al), silver (Ag), tin (Tin), gold (Au), solder, etc. However, the material of the connection terminal 400 is not limited thereto. Meanwhile, the connection terminal 400 may be formed as a multi-layer or single layer. For example, when formed in a multi-layer structure, the connection terminal 400 may include a copper pillar and a solder. When formed as a single layer, the connection terminal 400 may include tin-silver solder or copper.

The core chips 100C may be stacked on the buffer chip 100B or another core chip 100C positioned thereunder through the bump 180 and an adhesive layer 200. The core chip 100C may be a relative concept with respect to the buffer chip 100B. The core chip 100C may include a number of memory devices in an integrated device layer. For example, the memory device may include a volatile memory device, such as DRAM, SRAM, or a non-volatile memory device, such as PRAM, MRAM, ferroelectric random-access memory (FeRAM), or RRAM. Therefore, the core chip 100C may be a memory chip.

In the semiconductor package 1000 of the present embodiment, the core chip 100C may be the semiconductor chip 100 of FIG. 4. The core chip 100C may include the semiconductor substrate 101, the multi-wiring layer 130, a lower electrode pad 160, an upper electrode pad 165, the through silicon via 170, and the bump 180. The semiconductor substrate 101 corresponds to the semiconductor substrate 101 of the semiconductor chip 100 of FIG. 4 and may include the integrated device layer 110. Additionally, the multi-wiring layer 130 may include an interlayer insulating layer 120 and the multi-wiring layer 130 of the semiconductor chip 100 of FIG. 4. The through silicon via 170 is as described above with respect to the through silicon via 170B of the buffer chip 100B. These through silicon vias 170 may be arranged in multiple rows in the first horizontal direction (X direction) or the second horizontal direction (Y direction) in a central portion of the core chip 100C.

The lower electrode pad 160 and the upper electrode pad 165 are as described above with respect to the lower electrode pad 160B and the upper electrode pad 165B of the buffer chip 100B. Meanwhile, the bump 180 may be arranged on the lower electrode pad 160.

In the semiconductor package 1000 of the present embodiment, the core chips 100C, each corresponding to the semiconductor chip 100 in FIG. 4, are arranged on the buffer ship 100B such that their active surfaces 101a face downward. The lower electrode pads 160 and the upper electrode pads 165 may be arranged in the upper bump area UBA and the lower bump area LBA, respectively. Additionally, the through silicon via 170 may also be arranged in the upper bump area UBA and the lower bump area LBA.

In the semiconductor package 1000 of the present embodiment, eight core chips 100C may be stacked on a buffer chip 100B. However, the number of core chips 100C stacked on the buffer chip 100B is not limited to 8. For example, one to seven or nine or more core chips 100C may be stacked on the buffer chip 100B.

In the semiconductor package 1000 of the present embodiment, the core chip 100C may be an HBM chip including DRAM devices. Accordingly, the semiconductor package 1000 of the present embodiment may be an HBM package. The HBM package may be manufactured by stacking individual DRAM chips, i.e., core chips 100C, respectively corresponding to the buffer chips 100B in a wafer state, sealing the same with the sealant 300, and then individualizing the same through a sawing process.

The sealant 300 may cover and seal the core chips 100C on the buffer chip 100B and the adhesive layer 200. The sealant 300 may seal the core chips 100C and protect the core chips 100C from external physical and chemical damage. The sealant 300 may include, for example, epoxy molding compound (EMC). However, the sealant 300 is not limited to EMC and may include various materials, such as epoxy-based materials, thermosetting materials, thermoplastic materials, ultraviolet (UV)-curable materials, etc. Additionally, the sealant 300 may include resin and include a filler. As illustrated in FIG. 14, the sealant 300 may cover an upper surface of the core chip 100C positioned in an uppermost portion thereof. However, without limitation, the sealant 300 may not cover the upper surface of the core chip 100C of the uppermost portion. That is, the upper surface of the core chip 100C of the uppermost portion may be exposed from the sealant 300.

As the semiconductor chip 100 according to one or more embodiments includes the lower metal layer 150 disposed on the lower surface of the semiconductor substrate 101, warpage caused by the difference in CTE between the upper metal layer 140 and the semiconductor substrate 101 may be alleviated. Accordingly, the yield of the semiconductor chip 100 may be improved during a manufacturing process. In addition, by increasing alignment through reduced warpage of the semiconductor chip 100, the assembly yield may be improved and cracks in the semiconductor chip 100 may be prevented.

According to the semiconductor package 1000 according to one or more embodiments, a semiconductor package with improved reliability may be provided using the semiconductor chip 100 including the lower metal layer 150.

While the disclosure has been particularly shown and described with reference to embodiments thereof, it will be understood that various changes in form and details may be made therein without departing from the spirit and scope of the following claims.

What is claimed is:

1. A semiconductor chip comprising:
a semiconductor substrate;
a through silicon via that vertically penetrates the semiconductor substrate;
an integrated device layer on a first surface of the semiconductor substrate and comprising integrated devices;
a multi-wiring layer on the integrated device layer and comprising layers of wires;
an upper metal layer on the multi-wiring layer and connected to the wires;
bump pads on a lower bump area on a second surface of the semiconductor substrate; and
a lower metal layer on the second surface of the semiconductor substrate, wherein the lower metal layer is on a periphery of the lower bump area.

2. The semiconductor chip of claim 1, wherein the lower metal layer comprises a material having a coefficient of thermal expansion (CTE) greater than a CTE of the semiconductor substrate.

3. The semiconductor chip of claim 1, wherein the lower metal layer is shaped as a plate on the second surface of the semiconductor substrate and does not to overlap with the lower bump area.

4. The semiconductor chip of claim 3, wherein the plate comprises a plurality of holes.

5. The semiconductor chip of claim 1, wherein the lower metal layer is shaped as a serpent extending in a first horizontal direction in a planar view.

6. The semiconductor chip of claim 5, wherein the serpent comprises a repeating serpentine structure having a horizontal width and a vertical width of about 0.1 μm to about 100 μm.

7. The semiconductor chip of claim 1, wherein the lower metal layer is shaped as a plurality of metal pads.

8. The semiconductor chip of claim 7, wherein the metal pads are shaped as circles with diameters of about 0.1 μm to about 100 μm.

9. The semiconductor chip of claim 1, wherein the lower metal layer is shaped as a plurality of metal lines.

10. The semiconductor chip of claim 9, wherein the metal lines are shaped as repeating square rings.

11. The semiconductor chip of claim 1, wherein the lower metal layer has a thickness of about 0.01 μm to about 100 μm.

12. The semiconductor chip of claim 1,
wherein the lower metal layer is on a lower metal layer area on the second surface of the semiconductor substrate, and
wherein the lower bump area comprises a first lower bump area extending in a first horizontal direction and a second horizontal direction perpendicular to the first horizontal direction, from a center of the second surface of the semiconductor substrate, and
wherein the lower metal layer comprises a first lower metal layer area and a second lower metal layer area, which are separated from the first lower bump area in the second horizontal direction and extend in the first horizontal direction.

13. The semiconductor chip of claim 12, wherein a first lower metal layer in the first lower metal layer area has a different shape from a second lower metal layer in the second lower metal layer area.

14. The semiconductor chip of claim 1,
wherein the semiconductor chip comprises a dynamic random-access memory (DRAM) chip, and
wherein the integrated device layer comprises DRAM devices.

15. A semiconductor chip comprising:
a semiconductor substrate;
a through silicon via that vertically penetrates the semiconductor substrate;
an integrated device layer on a first surface of the semiconductor substrate and comprising integrated devices;
a multi-wiring layer on the integrated device layer and comprising layers of wires;
an upper metal layer on the multi-wiring layer and connected to an uppermost wire of the multi-wiring layer through a via contact, the upper metal layer being on an upper metal layer area of the first surface of the semiconductor substrate;
an upper bump pad on an upper bump area of the first surface of the semiconductor substrate;
a lower bump pad on a lower bump area of a second surface of the semiconductor substrate; and
a lower metal layer on a lower metal layer area of the second surface of the semiconductor substrate, the lower metal layer area being on a periphery of the lower bump area,
wherein the lower metal layer comprises a material having a coefficient of thermal expansion (CTE) greater than a CTE of the semiconductor substrate, and
wherein the lower metal layer is shaped as one of: a plate, a serpent, a plurality of metal pads, or a plurality of metal lines.

16. A semiconductor package comprising:
a first semiconductor chip; and
at least one second semiconductor chip stacked on the first semiconductor chip, wherein the at least one second semiconductor chip comprises:
a semiconductor substrate;
a through silicon via that vertically penetrates the semiconductor substrate;
an integrated device layer on a first surface of the semiconductor substrate and having integrated devices;
a multi-wiring layer on the integrated device layer and comprising layers of wires;
an upper metal layer on the multi-wiring layer and connected to the wires;
bump pads on a lower bump area on a second surface of the semiconductor substrate; and
a lower metal layer on the second surface of the semiconductor substrate,
wherein the lower metal layer is on a periphery of the lower bump area, and
wherein the at least one second semiconductor chip is stacked such that a first surface of the at least one second semiconductor chip faces the first semiconductor chip.

17. The semiconductor package of claim 16, wherein the lower metal layer comprises a material having a coefficient of thermal expansion (CTE) greater than a CTE of the semiconductor substrate.

18. The semiconductor package of claim 16, wherein the lower metal layer has a thickness of about 0.01 μm to about 100 μm.

19. The semiconductor package of claim 16, wherein the lower metal layer is shaped as a plate or a serpent extending in a first horizontal direction in a planar view.

20. The semiconductor package of claim 16, wherein the lower metal layer is shaped as a plurality of metal pads or metal lines.
